(19) United States
(12) Patent Application Publication
(10) Pub. No.: US 2012/0118853 A1
(43) Pub. Date: May 17, 2012

(54) MANUFACTURING METHOD OF MASTER DISK FOR PATTERNED MEDIUM AND MAGNETIC RECORDING DISK MANUFACTURING METHOD

(76) Inventors: Munehiro OGASAWARA, Hiratsuka-shi (JP); Yoshiyuki KAMATA, Tokyo (JP); Akira KIKITSU, Yokohama-shi (JP)

(21) Appl. No.: 13/356,936

(22) Filed: Jan. 24, 2012

Related U.S. Application Data
(63) Continuation of application No. PCT/JP2009/063508, filed on Jul. 29, 2009.

(51) Int. Cl. C23F 1/02; B29C 59/16; C23C 14/00; B29C 33/38

(52) U.S. Cl. 216/22; 264/219; 264/446; 427/523; 427/524

(57) ABSTRACT

According to one embodiment, a method for manufacturing a master disk for discoid patterned medium having a plurality of sectors arranged in a circumferential direction, the plurality of sectors including a recording data portion and a servo data portion that includes a sector identification region having gaps formed in a linear pattern is provided. An imprint master disk having a linear pattern which is common to the sectors before the gaps are formed in the sector identification region and including at least one pattern of the sector is prepared, imprinting is repeated in the circumferential direction by using the imprint master disk to form patterns of a discoid patterned medium on a substrate, and a sector identification pattern is formed in each sector by forming gaps in the linear pattern of each sector identification region among the patterns formed on the substrate.

### CROSS-REFERENCE TO RELATED APPLICATIONS

This application is a Continuation Application of PCT Application No. PCT/JP2009/063508, filed Jul. 29, 2009, the entire contents of which are incorporated herein by reference.

### FIELD

Embodiments described herein relate generally to a manufacturing method of a master disk for patterned medium for manufacturing a master disk for discoid patterned medium and a magnetic recoding disk manufacturing method.

### BACKGROUND

In recent years, in a magnetic recording device such as a hard disk drive or the like, much attention has been paid to patterned medium. In order to form a master disk of a patterned medium, a Ni film is embedded in a pattern opening portion by sputtering and plating after forming a resist pattern on a Si substrate by electron beam lithography. Subsequently, after a Ni film is adhered to a supporting substrate, a father master disk of Ni is formed by separating the Ni film and supporting substrate from the resist pattern. Then, a mother master disk is formed by an imprint process using the father master disk and a plurality of stampers are further formed. Next, a large number of media (magnetic recording media) can finally be formed by using the plurality of stampers.

However, the following problem occurs in this type of method. That is, it is necessary to draw a pattern on the entire surface of a disk by using an electron-beam drawing device to form a father master disk, and therefore, there occurs a problem that a long time is taken to form the father master disk.

Therefore, recently, a method for forming a data area by imprinting and forming a servo area by electron-beam drawing is proposed (JP-A 2005-100499 [KOKAI]). However, it is necessary to align the data area and servo area in the radial direction with high precision, and if the data area and servo area are separately formed, it is extremely difficult to align the areas. Further, since the entire portion of the servo area is drawn by use of an electron beam, it still takes a long time to form the servo area.

Further, there is provided a method for repeatedly imprinting a small stamper to form a stamper although it is not a master disk for patterned medium (JP-A 2008-055908 [KOKAI]). However, this method can be applied to a case wherein a pattern to be formed is a repetition of exactly the same pattern, but cannot be applied to a pattern that is different in a sector number or the like for each sector as in the patterned medium.

### BRIEF DESCRIPTION OF THE DRAWINGS

FIG. 1 is a view showing the schematic structure of a magnetic recording device using a patterned medium.

FIG. 2 is a diagram showing the locus of a magnetic head.

FIGS. 3A to 3C are views showing states in which magnetic substances are arranged in the form of an arc.

FIG. 4 is a view showing the configuration of a patterned medium.

FIG. 5 is a diagram showing the arrangement relationship between a servo data portion and a recording data portion in a sector.

FIG. 6 is a diagram showing the manufacturing procedure of a master disk for patterned medium according to a first embodiment.

FIG. 7 is a view showing an imprint father master disk for a common sector.

FIGS. 8A to 8C are views showing steps of forming a sector identification pattern in a sector identification area.

FIGS. 9A to 9T are views showing a patterned medium manufacturing process according to the first embodiment.

FIG. 10 is a view showing a patterned medium manufacturing process according to a second embodiment.

FIG. 11 is a view showing a patterned medium manufacturing process according to a fourth embodiment.

### DETAILED DESCRIPTION

According to one embodiment, a method for manufacturing a master disk for discoid patterned medium having a plurality of sectors arranged in a circumferential direction, the plurality of sectors including a recording data portion and a servo data portion that includes a sector identification region having gaps formed in a linear pattern is provided. An imprint master disk having a linear pattern which is common to the sectors before the gaps are formed in the sector identification region and including at least one pattern of the sector is prepared, imprinting is repeated in the circumferential direction by using the imprint master disk to form a pattern of a discoid patterned medium on a substrate, and a sector identification pattern is formed in each sector by forming gaps in the linear pattern of each sector identification region among the patterns formed on the substrate.

The detail of the embodiment is explained below with reference to the drawings.

### First Embodiment

FIG. 1 is a perspective view showing the schematic structure of a hard disk drive (magnetic recording device) using a patterned medium.

The device is of a type using a rotary actuator. In the internal portion of a casing 10, a magnetic disk (magnetic recording medium) 11, a spindle motor 12, a head slider 16 including a magnetic head, a head suspension assembly (suspension 15 and actuator arm 14) that supports the head slider 16, a voice coil motor 17 and a circuit board are provided.

The magnetic disk 11 is a patterned medium. The magnetic disk 11 is mounted on and rotated by the spindle motor 12 to record various types of digital data items according to a vertical magnetic recording system. In this case, the device may include a plurality of magnetic disks 11.

The head slider 16 that records and plays back information with respect to the magnetic disk 11 is mounted on the tip of the thin-film suspension 15. In this case, the head slider 16 has a magnetic recording head mounted on a portion near the tip. The magnetic head incorporated in the head slider 16 is a so-called compound head. The compound head includes a write head of a single magnetic pole structure and a read head using a shield MR playback element (GMR, TMR or the like).

When the magnetic disk 11 is rotated, the pressing pressure caused by the suspension 15 balances the pressure occurring on the medium-facing surface (ABS) of the head slider 16. Then, the medium-facing surface of the head slider 16 is held with a preset floating distance from the surface of the magnetic disk 11. In this case, a so-called “contact-running type” in which the head slider 11 contacts the magnetic disk 11 may be used.

The suspension 15 is connected to one end of the actuator arm 14 having a bobbin portion that holds a drive coil, which is not shown in the drawing. The voice coil motor 17, which is a type of linear motor, is provided on the other end of the actuator arm 14. The voice coil motor 17 may be configured by a drive coil, which is not shown in the drawing, wound around the bobbin portion of the actuator arm 14, and a magnetic circuit formed of permanent magnets arranged in opposition to sandwich the coil and counter-yokes.

The actuator arm 14 is held by ball bearings, which are not shown in the drawing, provided in two portions in the vertical direction of a bearing portion 13, the arm being freely rotatable and slidable by means of the voice coil motor 17. As a result, the magnetic recording head can be moved to a desired position on the magnetic disk 11.

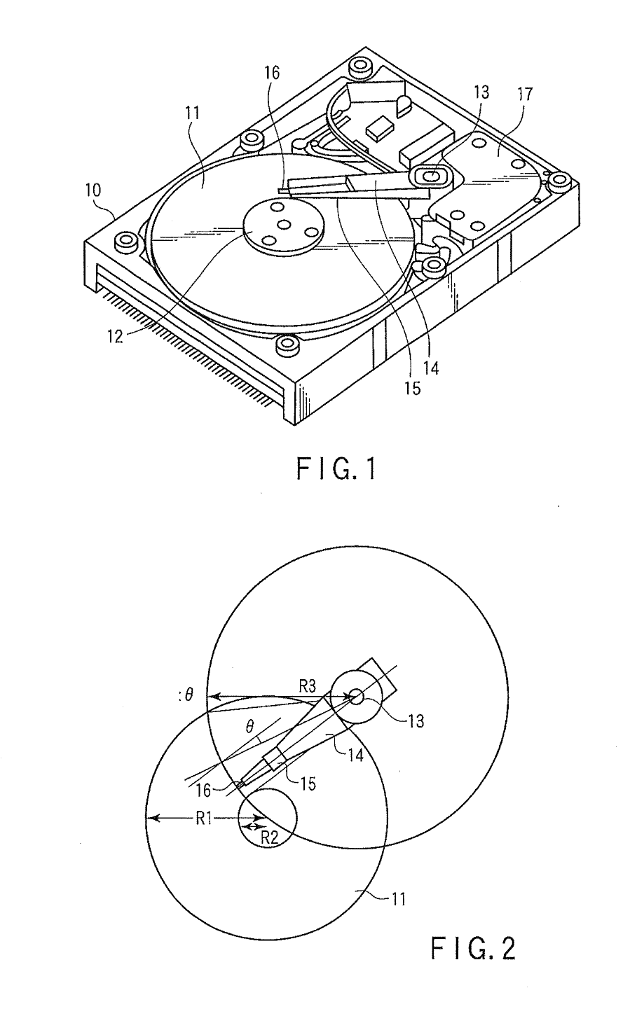

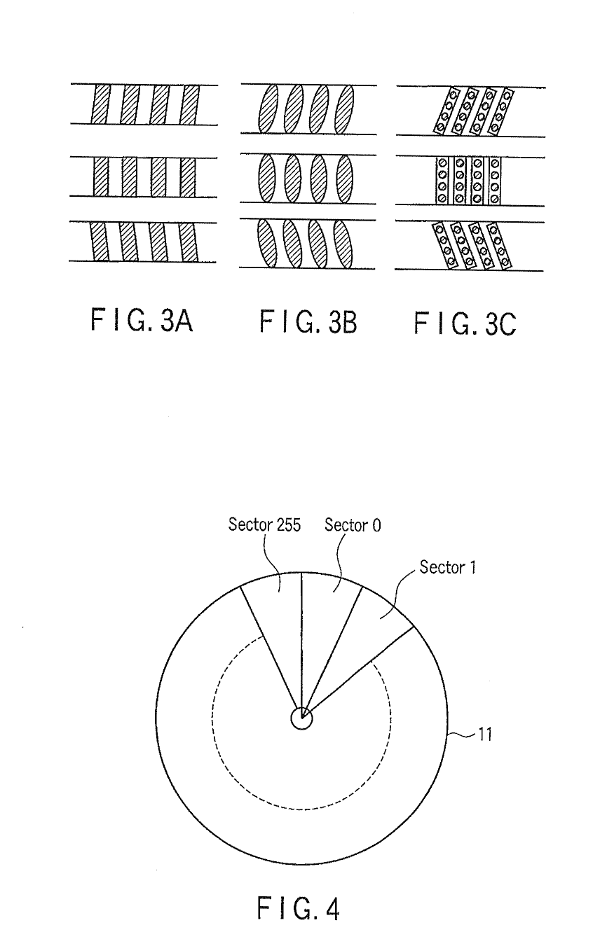

In the magnetic recording device with the above structure, since the locus of the magnetic head draws an arc as shown in FIG. 2, each boundary of the sector becomes a part of the arc. In FIG. 2, R1 indicates an outer diameter of the magnetic disk 11, R2 indicates an inside diameter of the magnetic disk 11 and R3 indicates a rotation radius of the magnetic disk. Further, the recording patterns have different inclinations in the radial direction depending on the radial position as shown in FIGS. 3A to 3C. In FIGS. 3A to 3C, the upper side indicates the outside region of the magnetic disk (a region at a long distance from the center of the disk) and the lower side indicates the inside region of the magnetic disk (a region at a short distance from the center of the disk). For convenience, the explanation is made below with the shape of the sector used as a part of a simple fan shape.

FIG. 4 is a plan view showing the schematic configuration of a discoid patterned medium according to this embodiment. The discoid magnetic disk 11 is divided into a plurality of sectors in the circumferential direction. For example, it is divided into 256 sectors from sector 0 to sector 255. The shape of the sector boundary is commonly set to an arc based on the relationship of the locus of a signal detection head, but the explanation is made below for simplicity on the assumption that it is linear.

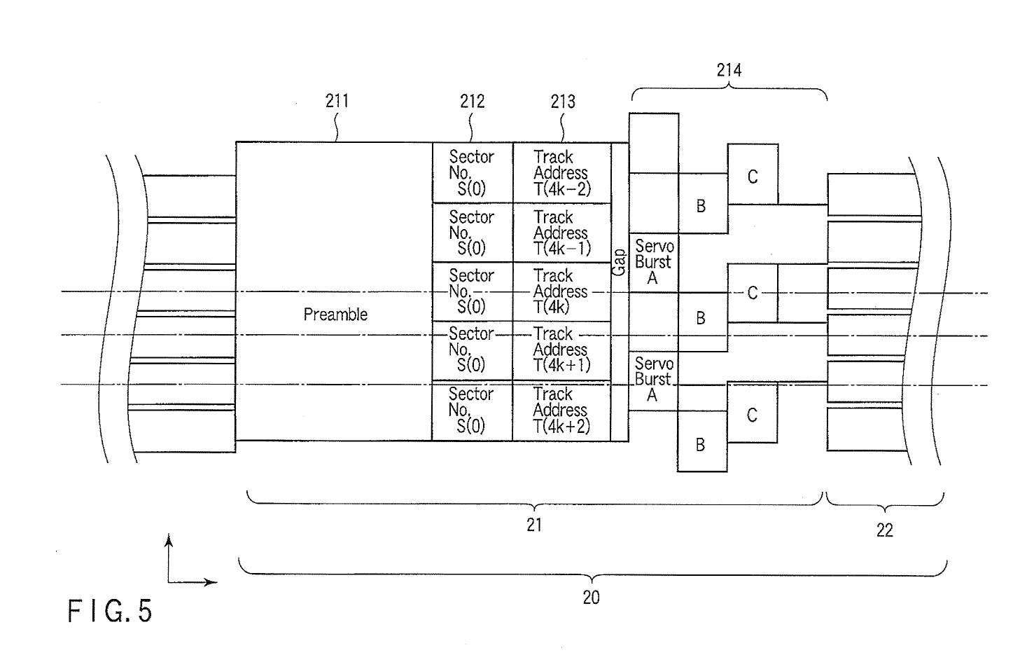

FIG. 5 is a diagram showing an enlarged portion near the boundary of adjacent sectors and showing the arrangement relationship between a servo data portion and a recording data portion in the sector. A sector 20 is divided into a servo data area 21 in which a servo pattern is formed and a recording data area 22 formed to hold recording data. Further, the servo data area 21 is divided into a preamble pattern 211 for rotation control, a sector information pattern 212 for sector identification, a track information pattern 213 for identifying a track in the radial direction, and a burst pattern 214 for aligning the positions of tracks. When the recording data area 22 is a continuous track, it becomes a so-called discrete track medium. When it is a shape divided for each bit, it becomes a so-called bit-patterned medium. This embodiment can be applied to each medium.

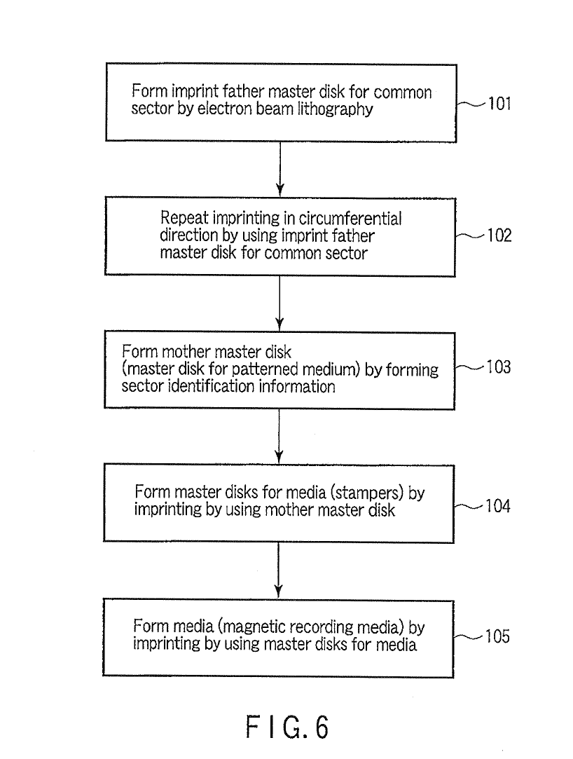

Next, the manufacturing method of a master disk for patterned medium that is the feature of this embodiment is explained with reference to the flowchart of FIG. 6.

In a semiconductor process, a certain determined pattern is repeatedly formed on a Si wafer in some cases. In such a case, a system called so-called step-and-repeat in which a pattern used as a unit is transferred plural times is adopted. However, the method cannot be directly applied to patterned medium as it is. This is because the patterns of the respective sectors are similar, but the address portions are different, and therefore, divided patterns equal in number to the sectors are necessary if it is simply applied. Therefore, it is difficult to obtain the merit of reducing the process time. The inventors of this application and others studied a method for solving this and resultantly found that the address portion could be divided into a portion commonly used in each sector and a portion additionally processed and the time could be extremely reduced by setting the additional processing portion as less as possible.

First, a common sector imprint father master disk corresponding to one (or plural) sector is formed by electron beam lithography (FIG. 6: 101). That is, pattern data of one sector portion among the patterned medium pattern is prepared.

Specifically, resist is coated on an imprint substrate and drawing is made based on common sector pattern data by using an electron beam drawing device. At this time, as the electron-beam drawing device, it is desirable to use a vector scan type drawing device using an XY stage. This is because a useless time occurs since an electron beam drawable region having a region in which no pattern exists is passed through in a device having a rotation stage moving in parallel with one axis. As the resist, positive resist is used. Next, a common sector imprint father master disk having a common sector pattern is formed via a conventional father master disk forming process.

In this case, a sector information pattern portion used for sector identification is set as a pattern in which only a common portion of the sector information pattern is formed. For example, as shown in FIG. 8A, it is set as a pattern having no gap. The thus determined pattern is prepared as a common sector pattern and further drawing data used for drawing the common sector pattern by the electron-beam drawing device is called common sector pattern data.

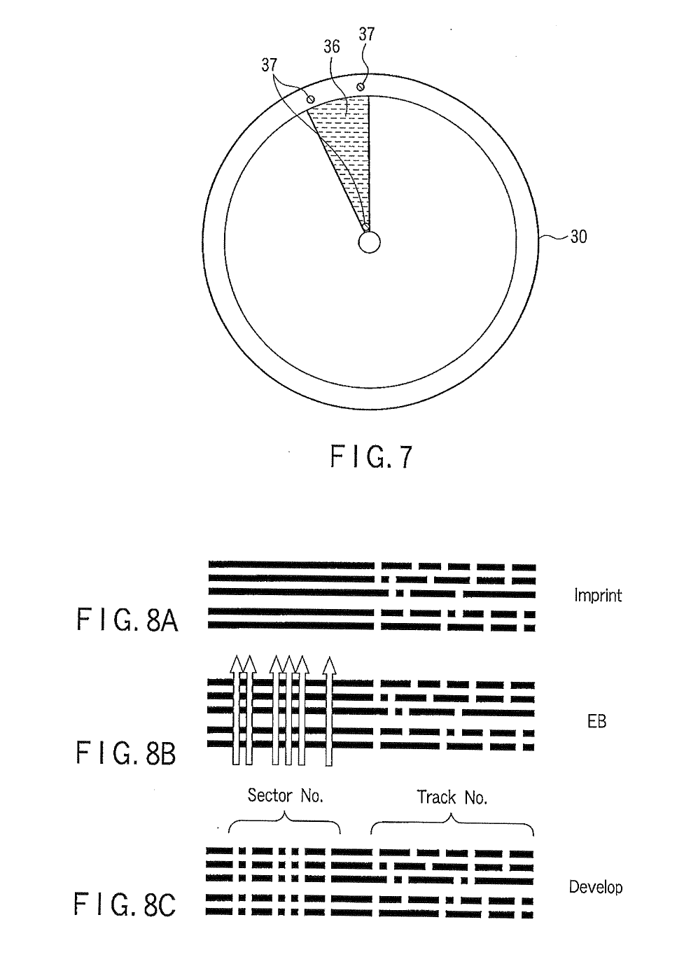

FIG. 7 is a plan view showing an imprint father master disk for a common sector. On a common sector imprint father master disk 30 formed of Ni, a common sector pattern 36 of one sector is formed in a fan-shaped region. Further, in the peripheral portion of the master disk 30, marks 37 for alignment in the circumferential direction and radial direction are provided in at least two portions. By referring to the marks 37, alignment can be performed at the time of imprinting with respect to the discoid substrate. Further, it is effective to previously form an alignment pattern such as a vernier pattern or the like, for example, in a connection portion of adjacent sectors in enhancing the alignment precision.

Next, common sector patterns are formed in all of the sectors by repeatedly imprinting in the circumferential direction by using a common sector imprint father master disk shown in FIG. 7 (FIG. 6: 102). Subsequently, sector identification information is formed by electron beam lithography to form a sector identification pattern. That is, as shown in FIG. 8B, an electron beam is applied to the linear pattern shown in FIG. 8A. By application of the electron beam, as shown in FIG. 8C, a sector identification pattern different for each sector is formed by forming gaps according to a preset rule. As a result, a mother master disk (master disk for patterned medium) is formed (FIG. 6: 103).

Next, a plurality of master disks for media (stampers) are formed by imprinting by using the mother master disk (FIG. 6: 104). Subsequently, a large number of media (magnetic recording media) are formed by imprinting by using the master disks for media (FIG. 6: 105).

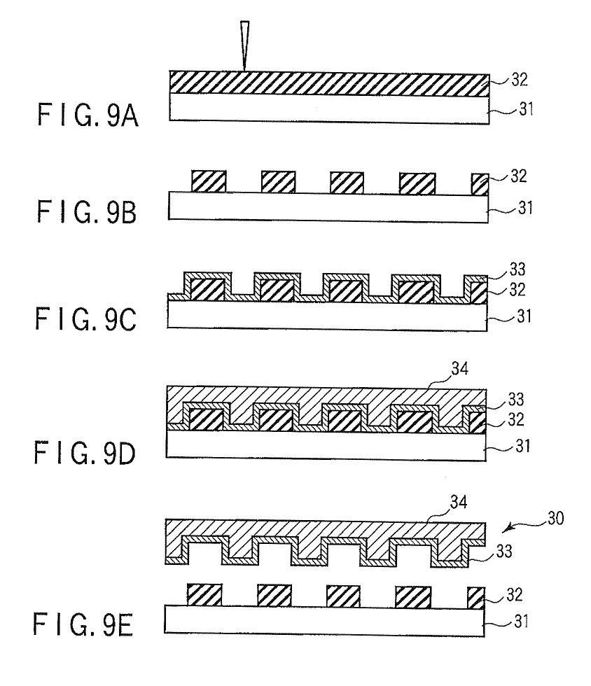

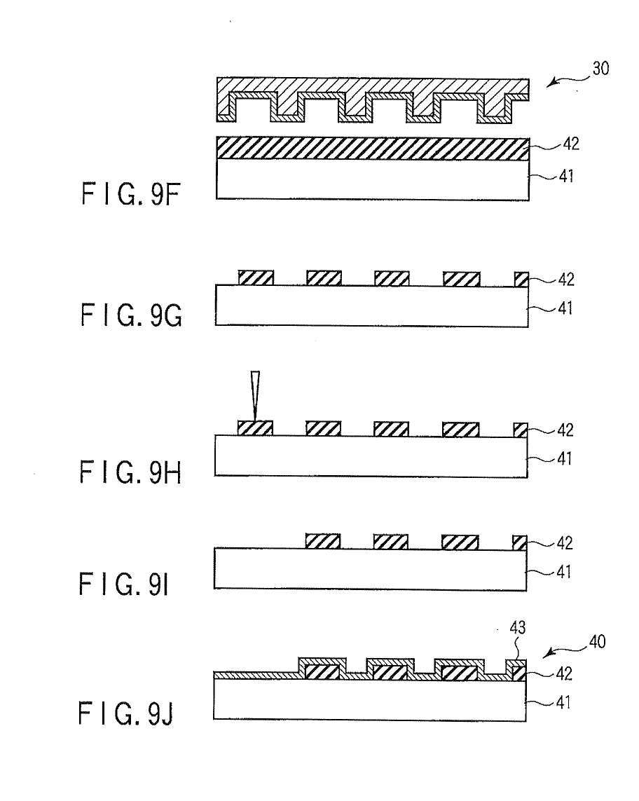

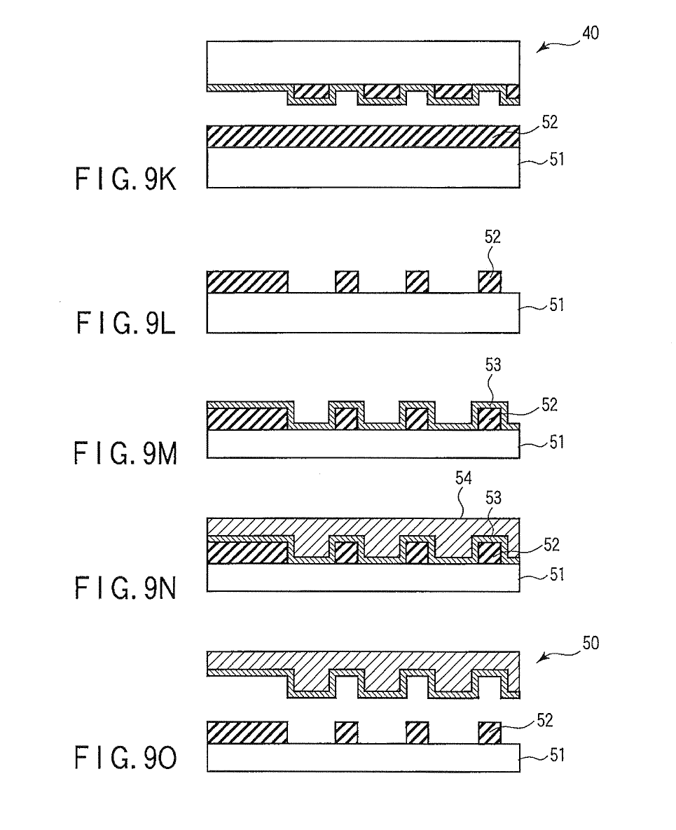

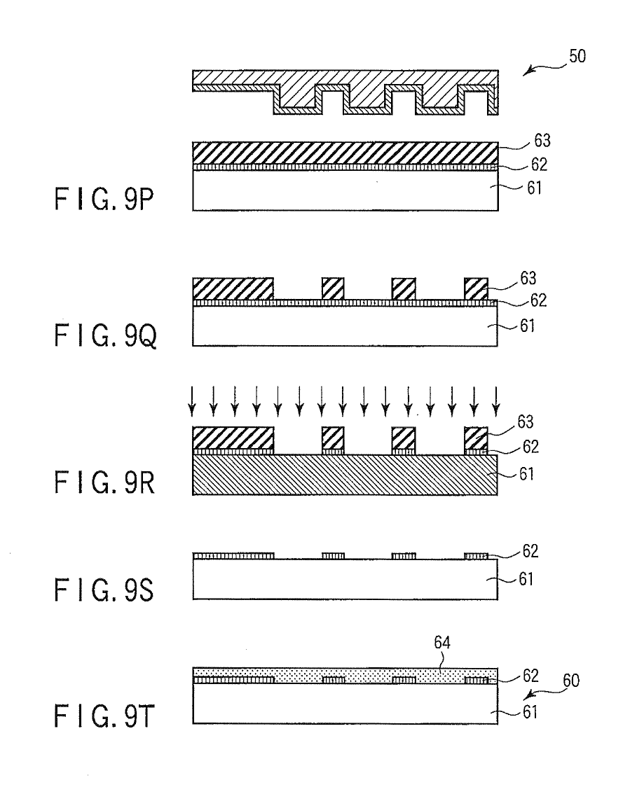

FIGS. 9A to 9T show a further detailed process.

First, as shown in FIG. 9A, a sample having positive resist 32 such as PMMA resist or the like coated on a discoid substrate 31 is prepared. Then, on a fan-shaped sector region on the sample, a desired pattern is drawn by means of an electron-beam drawing device. After this, as shown in FIG. 9B, a resist pattern is formed by developing the resist 32. Then, as shown in FIG. 9C, a Ni film 33 is formed on the surface of the resist 32 and the exposed surface of the substrate by sputtering, and then, as shown in FIG. 9D, a Ni film 34 is plated to make flat the surface.

Next, after the Ni film 34 is adhered to a supporting substrate (not shown), as shown in FIG. 9E, the Ni films 33, 34 are separated from the resist 32 and substrate 31. As a result, a common sector imprint father master disk 30 as shown in FIG. 7 is formed.

Next, as shown in FIG. 9F, an object obtained by coating a material film 42 having a characteristic of, for example, positive resist such as PMMA resist or, the like on a discoid substrate (first substrate) 41 is prepared. Then, imprinting is made on the material film 42 by a thermal imprint method by using the common sector imprint father master disk 30. As a result, as shown in FIG. 9G, a common sector pattern is formed. In this case, common sector patterns equal in number to the sectors are formed on the entire surface of the discoid substrate 41 by rotating the substrate 41 or rotating the common sector imprint father master disk 30.

Next, as shown in FIG. 9H, a sector identification pattern is drawn on the discoid substrate on which common sector patterns of the number of sectors are formed on the entire substrate surface by using an electron-beam drawing device. After this, as shown in FIG. 9I, a sector identification pattern is formed via the development process. That is, as shown in FIG. 8B, sector identification information is formed in addition to the common sector pattern formed by imprinting by forming gaps by electron beam lithography. In this case, gaps are formed in the same position of a plurality of linear patterns in the circumferential direction by scanning an electron beam in the radial direction.

Next, as shown in FIG. 9J, a Ni film 43 is sputtered to form a mother master disk (master disk for patterned medium) 40 of a pattern for patterned medium.

Next, as shown in FIG. 9K, an object obtained by coating a material film 52 having a characteristic of, for example, positive resist such as PMMA resist or the like on a discoid substrate 51 is prepared. Then, imprinting is made on the material film 52 by a thermal imprint method by using the mother master disk 40 to form a pattern as shown in FIG. 9L.

Next, as shown in FIG. 9M, a Ni film 53 is formed on the surface of the resist 52 and the exposed surface of the substrate 51 by sputtering, and then, as shown in FIG. 9N, a Ni film 54 is plated to make flat the surface.

Next, after the Ni film 54 is adhered to a supporting substrate (not shown), the Ni films 53, 54 are separated from the resist 52 and substrate 51 as shown in FIG. 9O. As a result, a master disk (stamper) 50 for patterned medium is copied.

Next, as shown in FIG. 9P, imprinting is made with respect to a sample in which a magnetic film 62 is formed on a substrate (second substrate) 61 and a resist film 63 is further formed thereon by using the stamper 50. As a result, a resist pattern as shown in FIG. 9Q is formed.

Next, as shown in FIG. 9R, after the magnetic film 62 is selectively etched by an RIE method with a pattern of the resist 63 used as a mask, the resist film 63 is removed as shown in FIG. 9S. After this, as shown in FIG. 9T, a protective film 64 is formed to make flat the surface and form a magnetic recording medium 60.

Thus, according to this embodiment, imprinting using an imprint master disk having a pattern of one sector is repeatedly made in a circumferential direction to form a pattern of a discoid patterned medium. After this, gaps are formed in the linear patterns of respective sector identification regions in the radial direction to form a sector identification pattern. As a result, a patterned medium master disk can be formed. In this case, since the pattern formation time by electron beam lithography or the like can be reduced, the manufacturing time and manufacturing cost required for formation of a patterned medium master disk can be reduced.

In this case, as shown in FIG. 8C, when an object having gaps formed in a line as a sector identification pattern is used, an electron beam may be used only to draw a straight line at a determined angle as shown in FIG. 8B, and therefore, the requirement for positional precision at the time of drawing can be significantly reduced. When it is independently formed by electron-beam drawing without forming a pattern in a circumferential direction of the sector identification pattern, extremely high drawing positional precision is required to make drawing in alignment with the other pattern in the radial direction. In the method described in FIGS. 8A to 8C, since a line in the radial direction is previously formed and exposure by an electron beam may be linearly performed in the radial direction, high pattern formation precision can be easily obtained.

Various forms can be considered as the sector identification pattern. If 256 types are identified, identification can be made based on whether or not gaps are present in at least eight portions, that is, an 8-bit pattern. Further, a pattern having an error correction function can be formed by increasing portions in which gaps are formed and increasing the number of bits of an identification signal.

Further, a servo characteristic of patterned medium formed according to the present embodiment was studied in detail, but it was found that the effect of enhancing the quality of a servo signal could be attained according to this embodiment. The studying result is shown below.

In the conventional method, a discoid sample having a resist coated on a silicon surface is placed on a pedestal on a stage that is rotatable and movable parallel to one axis, and is moved linearly at constant speed while the pedestal is rotated at a constant rate of rotation. Then, when the position on the sample surface to which the electron beam is to be applied reaches the application position of the electron beam, the electron beam is applied. After this, substantially concentric patterns can be formed on the disk by developing the sample. Next, a Ni film is plated on a film formed by sputtering a Ni film, for example. Then, after the Ni film by plating is adhered to a supporting substrate, a process of separating the Ni film from the resist pattern by sputtering and further removing a resist residual substance is performed. As a result, a Ni father master disk can be formed. A mother master disk having an inverted concavo-convex form is formed by performing an imprint process by using the father master disk, and further, a large number of copies of the medium master disk for each of them can be formed by imprinting.

In this case, the time required for forming a pattern on the entire surface of the disk is approximately determined based on the area of a region in which the pattern is formed, the area of the alignment unit (that is hereinafter referred to as a pixel) for a position to which the electron beam is applied, the electron beam current density and resist sensitivity. If the pixel is a square with the length L of one side, the number of pixels increases in inverse proportion to the square of L with miniaturization of L since the area of the pixel is L². For example, if the resist sensitivity is set to 30 μC/cm², the length of one side of the square pixel is set to 30 nm, the current density is set to 1000 A/cm² and the diameter of a region in which a pattern is formed is 5 cm, the area is approximately 78.5 cm², and the number of pixels is 8.7×10¹². Since the application time of the electron beam for each pixel is 30 ns, the application time of at least approximately 72 hours is required. If the length of one side of the pixel becomes 20 nm, a time twice that or more is required.

Generally, since the time becomes several hours at most even if the sputter time and plating time are added, a large portion of the time in the above process becomes the time for electron-beam drawing.

The electron-beam drawing device is configured by a large number of elements such as a lens power source, electron gun, amplifier and the like and stage series and the like. In drawing over a long period of 72 hours by the conventional method, high stability is required for all of them. This leads to not only deterioration in precision but also an increase in the probability of occurrence of a defect such as a pattern error and the like. Particularly, since the drawing time increases while it is required to enhance the drawing precision if the pattern is miniaturized, the difficulty increases.

On the other hand, in the method described in the present embodiment, since the time for pattern drawing of a master disk by an electron beam is extremely short, the request for stability of the electron-beam drawing device can be greatly reduced. Conversely, extremely high stability can be attained with the same device. Particularly, since the servo portion only draws a pattern intersecting at right angles with that obtained based on the common pattern, the request for precision in the radial direction can be extremely reduced and the precision for pattern formation of the track portion can be greatly enhanced.

As described before, when a sector identification pattern is additionally formed by imprinting, pressure is further applied to a miniaturized pattern already formed. Therefore, the pattern is deformed and formation of a desired pattern becomes difficult. This leads to a lowering in the yield of articles from the viewpoint of a tracking characteristic.

The above problem can be alleviated by using an electron beam lithography technology. That is, a variation in the chemical characteristic is produced in resist at the electron beam exposure time and a variation in the shape is caused by dissolving an exposed portion by a chemical process called development. Therefore, deformation of a pattern as in a case where an imprinting method is used can be alleviated. When a sector identification pattern is formed by development after the electron beam exposure, it is desirable to use a device of high acceleration of 50 to 100 kV, for example. Scattering of an electron beam in the resist can be suppressed by using a high-acceleration electron beam and the shape of a pattern to be formed after development can be set closer to a vertical form.

As described above, according to the present embodiment, particularly, the method using the electron beam lithography for formation of a sector identification signal is effective in enhancing the reliability of tracking. When the track pitch is larger than 100 nm, the effect may be small. However, when patterned medium is used as future high-density HDD medium, it seems that the effect of this embodiment becomes larger, particularly, in the track pitch smaller than 100 nm.

When imprinting is performed, a common sector pattern can be formed by using optical imprinting using UV curable resin. As an identification pattern forming method that does not depend on electron beam lithography including a case where optically cured resin does not become positive electron beam resist, a sector identification pattern can be formed by using gas-assist etching or sputtering by use of a focused ion beam. In the case of sputtering by use of a focused ion beam, there occurs a problem that a case where reattachment tends to occur, and damage occurs in some cases, but an advantage that pattern drawing can be performed without the necessity of development is attained. When gas-assist etching is used, there occurs a problem of contamination of gas that requires a process for gas, but an advantage that a process less influenced by damage can be performed is attained.

Further, ion-beam lithography can be used instead of sputtering by the focused ion beam. In this case, the possibility that ions damage the substrate must be considered. Further, when resist has sensitivity with respect to the wavelengths of X-rays and light used in X-ray lithography, EUV lithography, optical lithography, the X-ray lithography, EUV lithography, optical lithography can be utilized instead of the electron-beam lithography. However, in each case, a highly precise mask is prepared and a lithography device itself becomes extremely large. Further, a problem that the resolution is deteriorated in comparison with the electron-beam lithography occurs. Therefore, the electron-beam lithography is most suitable.

### Second Embodiment

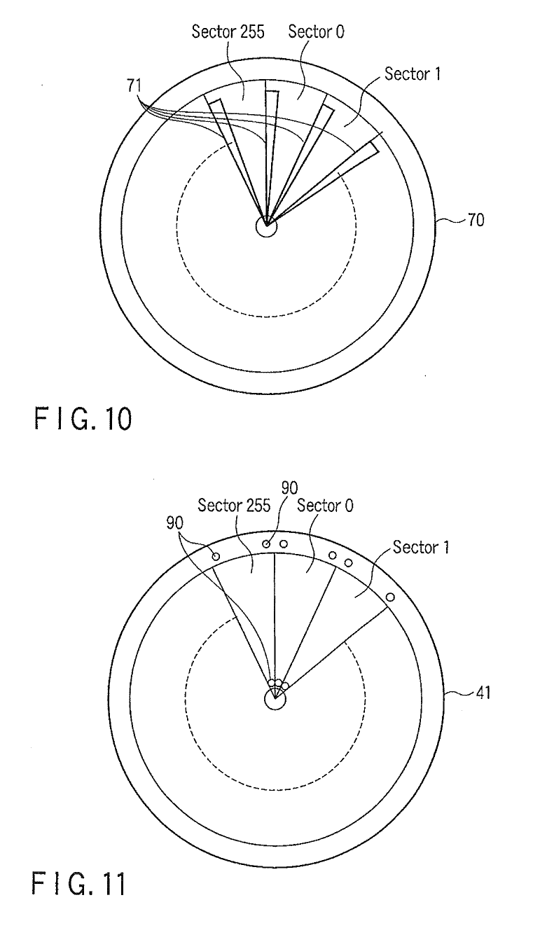

FIG. 10 is a view for illustrating a manufacturing method of a master disk for patterned medium according to a second embodiment.

This embodiment is different from the first embodiment explained before in a formation method of a sector identification pattern.

In the state of FIG. 9G in which the process 102 in FIG. 6 is terminated, an identification pattern can be formed by performing ion-beam etching by using a stencil mask 70 exclusive for a sector identification pattern as shown in FIG. 10. In this case, sector identification patterns 71 are formed in respective sector identification regions corresponding to respective sectors in the stencil mask 70. As a result, the sector identification patterns can be simultaneously formed with respect to all of the sectors. Therefore, an attempt can be made to reduce the manufacturing time and manufacturing cost.

Further, when the stencil mask is used, an advantage that the process time can be markedly reduced is attained, but a problem that the cost for formation of a stencil mask and high-precision mask position control are required occurs. One of the methods to be adopted is determined based on the specification/application of a magnetic recording medium and the effect of the embodiment can be attained with any one of the methods.

For example, it is assumed that one patterned medium is configured by 256 sectors. Then, according to the method explained above, in the process of formation of a master disk for the patterned medium, the time for forming a fine pattern of the patterned medium can be reduced to 1/256 in comparison with the conventional method. Even when the time required for a process of forming an imprint master disk and a process for forming a sector identification pattern is included, the time for formation of a master disk can be extremely reduced.

Further, with the method of this embodiment, since the respective processes can be performed by using different devices, the time required for formation of a disk can be set to several tens of minutes for each sheet if the operations are performed in parallel. Further, when the method of this embodiment is used, the same pattern can be formed with high precision as each sector. Therefore, an advantage that the servo characteristic becomes highly precise and equal in all of the sectors and the adjustment becomes easy is attained.

### Third Embodiment

Next, a manufacturing method of a master disk for patterned medium according to a third embodiment is explained.

As a process for forming gaps in a linear pattern, electron beam lithography as in the first embodiment and a method of performing selective etching by use of an ion beam using a stencil mask as in the second embodiment are not limited, but imprinting can be used.

In this embodiment, a discoid imprint master disk for formation of an identification pattern is previously formed and a sector identification pattern is formed by use of this after formation of a common sector pattern. At this time, on the master disk, sector identification patterns are formed in respective sector identification regions corresponding to respective sectors like the patterns 71 of FIG. 10. As a result, the sector identification patterns can be simultaneously formed with respect to all of the sectors. Therefore, an attempt can be made to reduce the manufacturing time and manufacturing cost.

Further, a pattern of a discoid imprint master disk for formation of identification patterns is extremely simple and the region is small. Therefore, even when pattern formation is performed by use of electron beam lithography, the time for applying an electron beam can be made short. However, since pressure is applied to the linear resist structure already formed to add an identification pattern, it becomes necessary to consider a problem that deformation of resist tends to occur.

### Fourth Embodiment

FIG. 11 is a view for illustrating a manufacturing method of a patterned medium according to a fourth embodiment.

In this embodiment, alignment marks 90 are previously provided on a pattern forming substrate 41 in correspondence to the alignment marks 37 of the father master disk 30. The mark 90 is used as an alignment mark at the imprinting time and is additionally used as an alignment mark at the time of imprinting, etching, focused ion beam processing and electron-beam drawing for formation of a sector identification pattern.

In this embodiment, alignment is performed by using the marks 37 formed on the father master disk 30 and the marks 90 formed on the pattern formation substrate 41 in the process 102 of FIG. 6 and the step shown in FIG. 9F. For this, the optical alignment technology may be used. As a result, alignment between the sectors of the father master disk 30 and the pattern formation substrate 41 can be performed with high precision. In this case, in the present embodiment, the marks 90 are arranged three for each sector, but at least two may be provided.

### Fifth Embodiment

Further, when the time for forming one sector pattern by electron-beam drawing is as short as tolerable, the common sector pattern can be formed to include a plurality of sectors. For example, even if it is configured by 512 sectors and one common sector pattern includes four sectors, the time for electron-beam drawing can be reduced to 1/128. In this way, the time for electron-beam drawing is extended, but the number of times of imprinting can be reduced. It is desirable to select the optimum number of sectors in reducing the whole manufacturing process.

When a plurality of sectors are included, the arrangement thereof is not limited to an arrangement in which they are arranged adjacent in an angular direction and various arrangements can be considered. For example, if the total number of sectors is even, they may be arranged two in positions separated by 180 degrees from each other, if it is a multiple of four, they may be arranged four at intervals of 90 degrees, and if it is a multiple of six, they may be arranged six at intervals of 60 degrees. In such a case, it becomes easy to mechanically set the center of the father mask having common sector patterns coincident with the center of the mother mask substrate.

(Modification)

This invention is not limited to the embodiments described above. In the embodiments, the imprinting method is used when the stamper is formed based on the mother master disk, but an electroforming method can be used. Further, the number of sector patterns formed on the father master disk (imprint master disk) is not limited to 1, 2, 4, 6 and can be adequately changed according to the specification. Further, materials of the substrate and a to-be-imprinted film formed thereon and a metal film formed by sputtering and plating can be adequately changed according to the specification.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a master disk for discoid patterned medium having a plurality of sectors arranged in a circumferential direction, the plurality of sectors including a recording data portion for recording data and a servo data portion that includes a sector identification region in which a sector identification pattern having gaps formed in a linear pattern along the circumferential direction is formed, the method comprising:
preparing an imprint master disk having a linear pattern which is common to the sectors before gaps are formed in the sector identification region and including at least one pattern of the sector,
forming patterns of a discoid patterned medium on a substrate by repeating imprinting that uses the imprint master disk, in the circumferential direction, and
forming a sector identification pattern in each sector by forming gaps in a radial direction in a linear pattern of each sector identification region among the patterns formed on the substrate.

2. The method of claim 1, wherein forming the sector identification pattern is performed by electron beam lithography.

3. The method of claim 2, wherein a plurality of linear patterns formed in the sector identification region are separated in a radial direction and arranged in parallel, and the electron beam lithography for forming the sector identification pattern forms gaps in the same circumferential position of each linear pattern of the same sector by scanning an electron beam in the radial direction.

4. The method of claim 1, wherein forming the sector identification pattern is performed by sputtering by using a focused ion beam.

5. The method of claim 1, wherein forming the sector identification pattern is performed by gas-assist etching.

6. The method of claim 1, wherein forming the sector identification pattern is performed by ion-beam etching by using a stencil mask exclusive for the sector identification pattern.

7. The method of claim 1, wherein a discoid imprint master disk for formation of an identification pattern is prepared and the gaps are simultaneously formed by imprinting by using this to form the sector identification pattern.

8. The method of claim 1, wherein superposition adjustment marks are previously formed on the imprint master disk in the circumferential direction and alignment of adjacent pattern positions is performed by using the marks when the imprinting is repeated.

9. A magnetic recording medium manufacturing method, comprising:
manufacturing a discoid patterned medium master disk having a plurality of sectors arranged in a circumferential direction, the plurality of sectors including a recording data portion for recording data and a servo data portion that includes a sector identification region in which a sector identification pattern having gaps formed in a linear pattern along the circumferential direction is formed, the manufacturing comprising;
preparing an imprint master disk having a linear pattern which is common to sectors before gaps are formed in the sector identification region and including at least one pattern of the sector
forming patterns of a discoid patterned medium on a first substrate by repeating imprinting that uses the imprint master disk, in the circumferential direction, and
forming a sector identification pattern in each sector by forming gaps in a radial direction in a linear pattern of each sector identification region among the patterns formed on the first substrate,
forming a stamper having the same pattern as or inverted pattern with respect to the pattern of the patterned medium master disk by imprinting using the patterned medium master disk,
preparing a second substrate comprising a magnetic layer and a resist provided on the magnetic layer,
forming the same pattern as the patterned medium master disk on the resist by imprinting using the stamper with respect to the second substrate, and
forming a pattern of the magnetic body by selectively etching the magnetic layer by using the pattern formed on the resist as a mask.

10. The method of claim 9, wherein forming the sector identification pattern is performed by electron beam lithography.

11. The method of claim 10, wherein a plurality of linear patterns formed in the sector identification region are separated in a radial direction and arranged in parallel, and the electron beam lithography for forming the sector identification pattern forms gaps in the same circumferential position of each linear pattern of the same sector by scanning an electron beam in the radial direction.

12. The method of claim 9, wherein forming the sector identification pattern is performed by sputtering by using a focused ion beam.

13. The method of claim 9, wherein forming the sector identification pattern is performed by gas-assist etching.

14. The method of claim 9, wherein forming the sector identification pattern is performed by ion-beam etching by using a stencil mask exclusive for the sector identification pattern.

15. The method of claim 9, wherein a discoid imprint master disk for formation of an identification pattern is prepared and the gaps are simultaneously formed by imprinting by using this to form the sector identification pattern.

16. The method of claim 9, wherein superposition adjustment marks are previously formed on the imprint master disk in the circumferential direction and alignment of adjacent pattern positions is performed by using the marks when the imprinting is repeated.
